(19) United States
(12) Patent Application Publication
(10) Pub. No.: US 2025/0060686 A1
(43) Pub. Date: Feb. 20, 2025

(54) SEMICONDUCTOR DEVICE

(71) Applicant: TAIWAN SEMICONDUCTOR MANUFACTURING COMPANY LTD., HSINCHU (TW)

(72) Inventors: HSU TUNG YEN, KAOHSIUNG CITY (TW); LING-SUNG WANG, TAINAN CITY (TW); CHEN-CHIEH CHIANG, KAOHSIUNG CITY (TW); BO HSIANG HUANG, TAINAN CITY (TW)

(21) Appl. No.: 18/451,866

(22) Filed: Aug. 18, 2023

(51) Int. Cl. G03F 9/00

(52) U.S. Cl. CPC G03F 9/7084

(57) ABSTRACT

Semiconductor device is provided. The semiconductor device includes a first pattern and a second pattern. The first pattern includes a first central part and a plurality of first noncentral parts surrounding the first central part and spaced apart from each other. The second pattern is at a second layer over the first layer of the substrate and at least partially overlapping the first pattern along a first direction passing through the first layer and the second layer. The plurality of first noncentral parts define a vortex arrangement.

### BACKGROUND

Silicon wafers are currently manufactured in a sequence of steps, where each step places a pattern of material on the wafer. By building up successive layers of patterned metal, patterned insulators, patterned photoresist, etc., transistor structures and/or other structures can be formed. In order for a final device to function correctly, it is essential that these patterns for successive layers are aligned correctly. For example, a contact layer, which resides vertically between an upper metal layer and a lower contact area, must be laterally arranged within a lateral width of the upper metal line and lower contact area, such that when formed, the contact layer extends vertically between the metal line and the contact area to form an electrical connection therebetween (e.g., ohmic connection). Misalignment of any kind can cause short circuits and/or connection failures, which in turn impact fab yield and profit margins.

Overlay control, sometimes abbreviated as OVL, defines the control of this pattern-to-pattern alignment between different layers. It plays an important role in semiconductor manufacturing, helping to monitor layer-to-layer alignment on multi-layer device structures.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a top view of a substrate that illustrates positions of measurement targets according to various aspects of the present disclosure.

FIG. 2 is a top view of the enlargement of a dotted region in FIG. 1.

FIG. 3A is a top view of a cell of a measurement target for aligning different layers of a substrate according to various aspects of the present disclosure.

FIG. 3B is a top view of a first layer of the measurement target as shown in FIG. 3A.

FIG. 3C is a top view of a second layer of the measurement target as shown in FIG. 3A.

FIG. 3D illustrates a top view of central parts and noncentral parts of the measurement target as shown in FIG. 3A.

FIG. 3E is a top view of a first layer of the measurement target as shown in FIG. 3A.

FIG. 4A is an enlarged view of region R1 as shown in FIG. 3B.

FIG. 4B is an enlarged view of region R2 as shown in FIG. 3B.

FIG. 5A is a top view of a measurement target including multiple cells for aligning different layers of a substrate according to various aspects of the present disclosure.

FIG. 5B is a top view of first layers of multiple cells of the measurement target as shown in FIG. 5A.

FIG. 5C is a top view of second layers of multiple cells of the measurement target as shown in FIG. 5A.

FIG. 6A is a top view of one of the cells of the measurement target as shown in FIG. 5A.

FIG. 6B is a top view of one of the cells of the measurement target as shown in FIG. 5A.

FIG. 6C is a top view of one of the cells of the measurement target as shown in FIG. 5A.

FIG. 6D is a top view of one of the cells of the measurement target as shown in FIG. 5A.

FIG. 7 is a top view of a measurement target including multiple cells for aligning different layers of a substrate according to various aspects of the present disclosure.

FIG. 8 is a flowchart of a method for manufacturing a layout of a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second,” and “third” describe various elements, components, regions, layers and/or sections, these elements, components, regions, layers and/or sections should not be limited by these terms. These terms may only be used to distinguish one element, component, region, layer or section from another. Terms such as “first,” “second,” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure relates in general to a semiconductor device including a measurement target for checking alignment accuracy, and more particularly, to a semiconductor device including a measurement target for aligning different layers of a substrate.

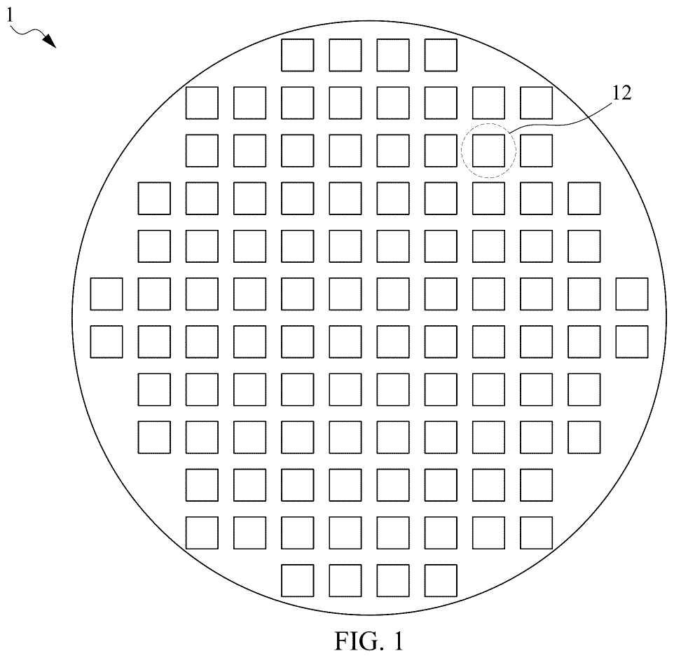

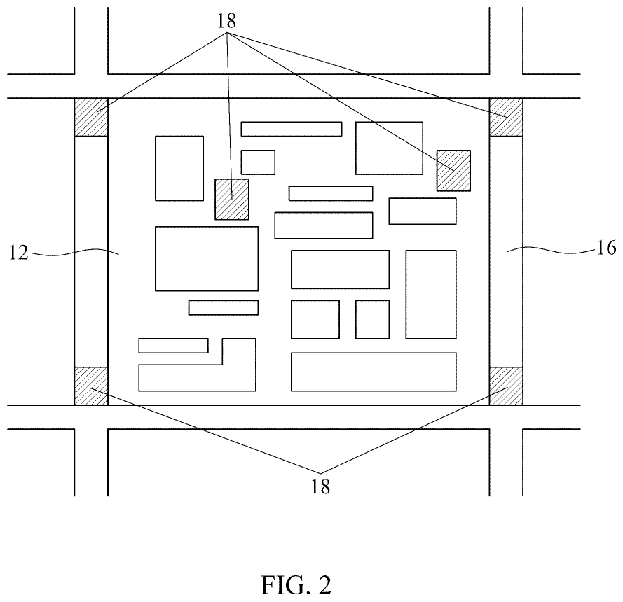

FIG. 1 is a top view of a substrate 1 according to various aspects of the present disclosure. FIG. 2 is a top view of the enlargement of a dotted region in FIG. 1.

As shown in FIG. 1 and FIG. 2, the substrate 1 (e.g., a wafer) includes a plurality of chips or dies 12 spaced apart from each other by scribe lines 16. Normally, measurement targets 18 (e.g., an overlay mark) are located on the scribe lines 16 at four corners of an edge of each chip or die 12 or located inside each chip or die 12 to measure whether the present layer, such as an opening of a photosensitive material, is precisely aligned with a pre-layer in the fabrication process.

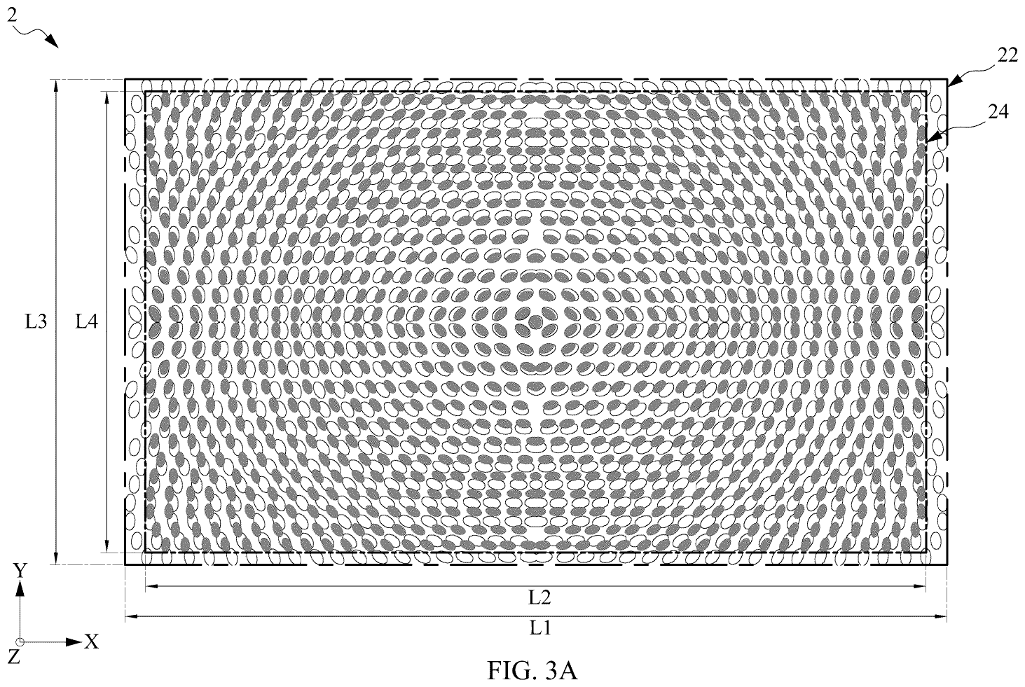

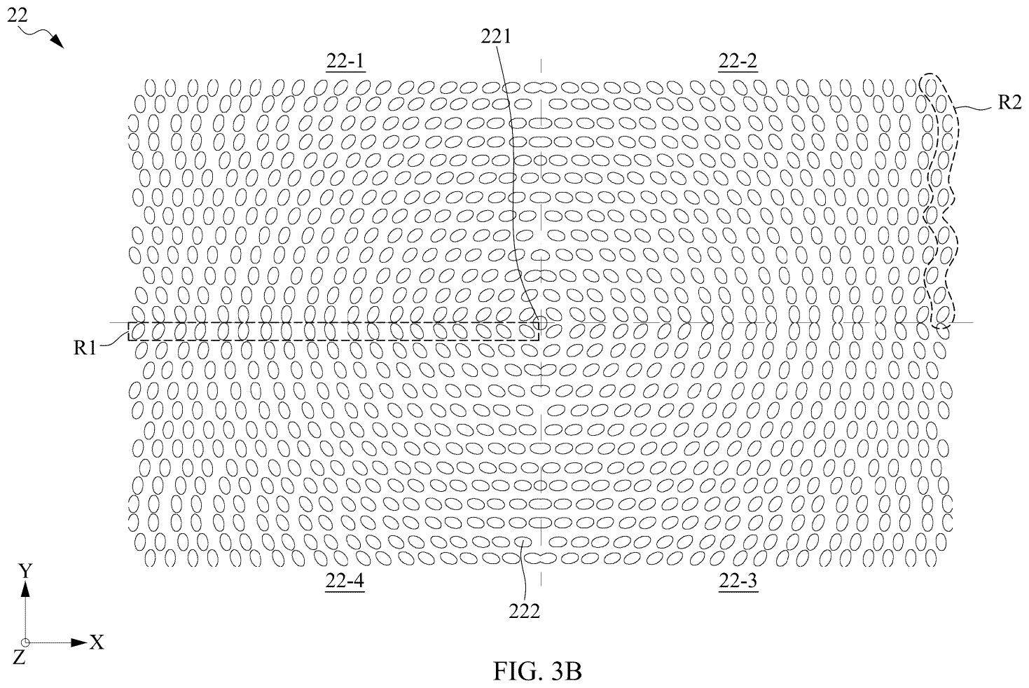

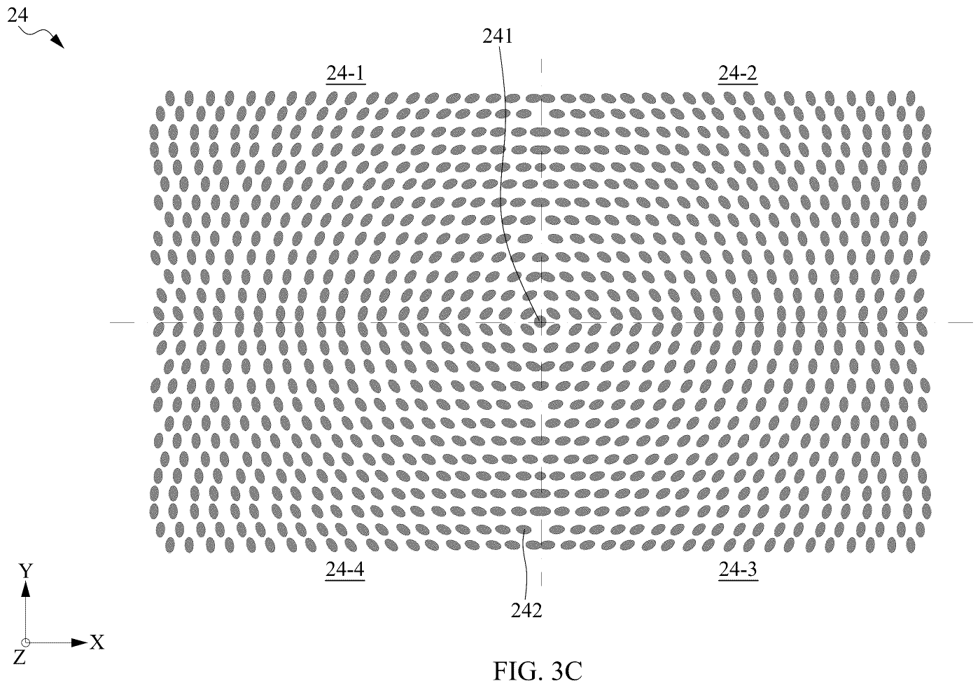

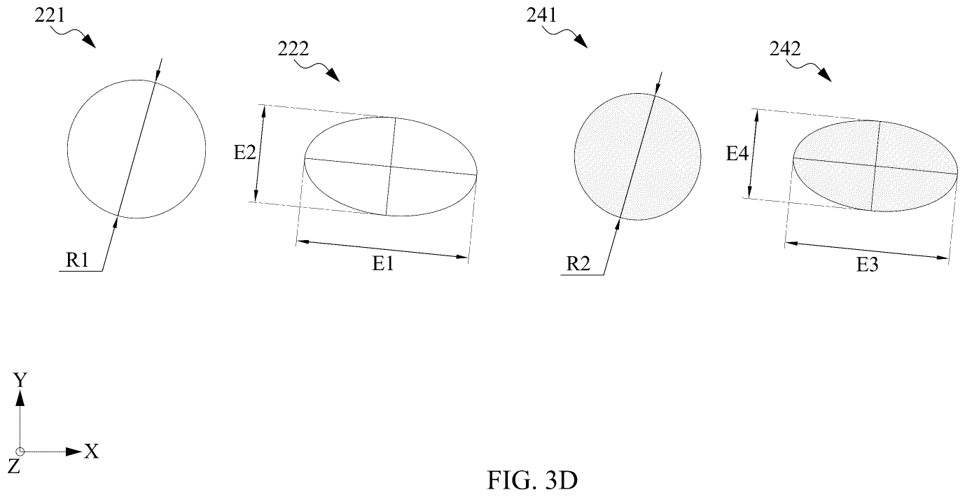

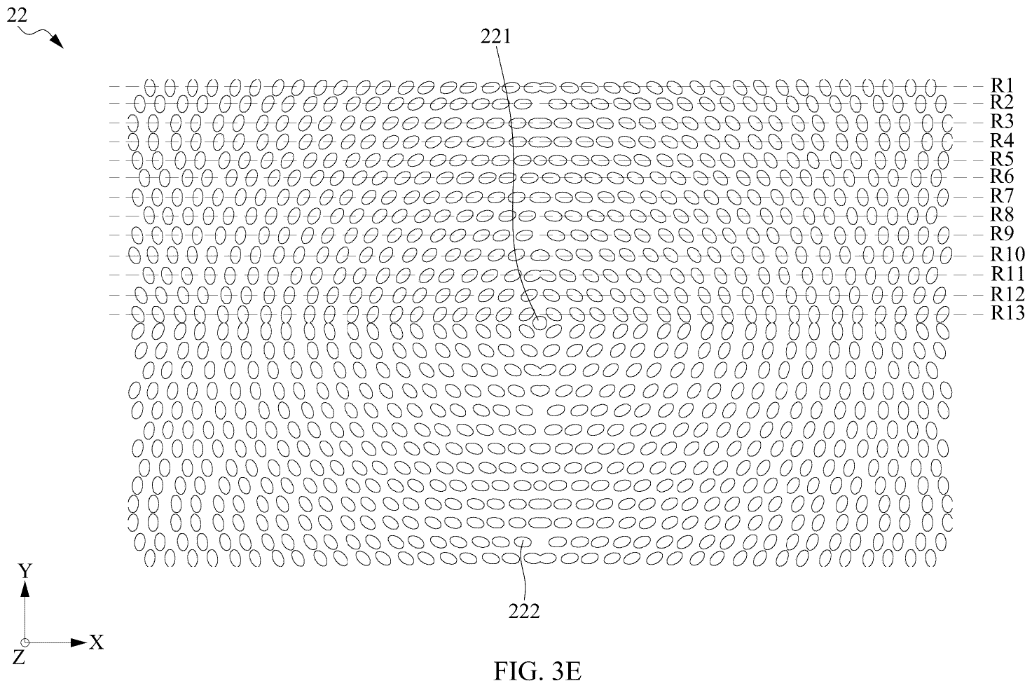

FIG. 3A to FIG. 3D illustrate a measurement target 2 for aligning different layers of a substrate according to various aspects of the present disclosure.

Referring to FIG. 3A, in some embodiments, the measurement target 2 includes a pattern 22 and a pattern 24. The patterns 22 and 24 can function as an overlay mark or function as a cell or a portion of an overlay mark. In some embodiments, the measurement target 2 is included in a semiconductor device.

The pattern 22 is located at a first layer of a substrate (e.g., a wafer). The pattern 24 is located at a second layer which is above or under the first layer of the substrate. In some embodiments, the pattern 22 at least partially overlaps the pattern 24 along the Z-axis, which passes through both the first layer and the second layer. In some embodiments, the pattern 22 represents a pattern of a pre-layer, such as a conductive feature (e.g., a metallization layer located at a level which is the same as that of the zero metal layer “MO” or located at a level which is the same as that of the metal gate), a semiconductor feature (e.g., a polysilicon layer located at a level which is the same as that of the poly-gate), and/or a dielectric feature (e.g., a dielectric layer located at a level which is the same as that of an interlayer dielectric “ILD”). In some embodiments, the pattern 24 represents a pattern of a present layer, such as an opening of a photosensitive material.

Refer to FIG. 3B, which is a top view of the pattern 22 as shown in FIG. 3A. In some embodiments, the pattern 22 includes a central part 221 and a plurality of noncentral parts 222. The central part 221 is located at the center of the pattern 22. In some embodiments, the central part 221 has a circular profile. In other embodiments, the central part 221 has a profile which is a regular polygon, such as a square, a hexagon, or other suitable polygons.

In some embodiments, the noncentral parts 222 surround the central part 221. In some embodiments, the noncentral parts 222 are spaced apart from each other. In some embodiments, each of the noncentral parts 222 has a profile different from that of the central part 221. In some embodiments, each of the noncentral parts 222 has an elliptical profile, an oval profile, or other suitable profiles. In some embodiments, the noncentral parts 222 may have a vortex arrangement. For example, the centers (e.g., gravity centers) of two abutting noncentral parts 222 are aligned along the X-axis, while the centers (e.g., gravity centers) of two abutting noncentral parts 222 are misaligned along the Y-axis. Each of the noncentral parts 222 may also be referred to as a subpart.

In some embodiments, the noncentral parts 222 are classified into sub-patterns 22-1, 22-2, 22-3, and 22-4, each of which occupies a quadrant of the pattern 22. The sub-pattern 22-1 abuts the sub-pattern 22-2. In some embodiments, the arrangement of the noncentral parts 222 of the sub-pattern 22-1 and the arrangement of the noncentral parts 222 of the sub-pattern 22-2 have a mirror symmetry. The plane (not shown) parallel to the Y-Z plane is a mirror plane between the sub-patterns 22-1 and 22-2. The sub-pattern 22-3 abuts the sub-pattern 22-2 and is opposite to the sub-pattern 22-1. The arrangement of the noncentral parts 222 of the sub-pattern 22-1 and the arrangement of the noncentral parts 222 of the sub-pattern 22-3 have a rotational symmetry. In some embodiments, a center of rotational symmetry between the sub-patterns 22-1 and 22-3 passes through or overlaps the central part 221. In some embodiments, the arrangement of the noncentral parts 222 of the sub-pattern 22-3 can be obtained by rotating the noncentral parts 222 of the sub-pattern 22-1 around the center of rotational symmetry by 180°. The sub-pattern 22-4 abuts the sub-pattern 22-1. The arrangement of the noncentral parts 222 of the sub-pattern 22-1 and the arrangement of the noncentral parts 222 of the sub-pattern 22-4 have a mirror symmetry. The plane (not shown) parallel to the X-Z plane is a mirror plane between the sub-patterns 22-1 and 22-4. In some embodiments, the noncentral parts 222 at the interface (not shown) of the sub-patterns 22-1, 22-2, 22-3, and/or 22-4 may be cut. As a result, each of the noncentral parts 222 at the interface of the sub-patterns 22-1, 22-2, 22-3, and/or 22-4 may be composed of a part of an elliptical profile or an imperfectly elliptical profile. Each of the noncentral parts 222 at the interface of the sub-patterns 22-1, 22-2, 22-3, and/or 22-4 has an irregular profile. For example, the noncentral parts 222 at the interface of the sub-patterns 22-1, 22-2, 22-3, and/or 22-4 may have a profile composed of two cut noncentral parts 222, such as a profile composed of two imperfectly elliptical profiles. In this disclosure, the central part can also be referred to as a central lattice or a central lattice point; the noncentral part can also be referred to as a noncentral lattice or a noncentral lattice point.

Refer to FIG. 3C, which is a top view of the pattern 24 as shown in FIG. 3A. In some embodiments, the pattern 24 includes a central part 241 and a plurality of noncentral parts 242. The central part 241 is located at the center of the pattern 24. In some embodiments, the central part 241 has a circular profile. In other embodiments, the central part 241 has a profile which is a regular polygon, such as a square, a hexagon, or other suitable polygons.

In some embodiments, the noncentral parts 242 surround the central part 241. Each of the noncentral parts 242 corresponds to a respective noncentral part 222. In some embodiments, each of the noncentral parts 242 has a profile different from that of the central part 241. In some embodiments, each of the noncentral parts 242 has an elliptical profile, an oval profile, or other suitable profiles. In some embodiments, the noncentral parts 242 may have a vortex arrangement. For example, the centers (e.g., gravity centers) of two abutting noncentral parts 242 are aligned along the X-axis; the centers (e.g., gravity centers) of two abutting noncentral parts 242 are misaligned along the Y-axis. Each of the noncentral parts 242 may also be referred to as a subpart.

In some embodiments, the noncentral parts 242 are classified into sub-patterns 24-1, 24-2, 24-3, and 24-4, each of which occupies a quadrant of the pattern 24. The sub-pattern 24-1 abuts the sub-pattern 24-2. The arrangement of the noncentral parts 242 of the sub-pattern 24-1 and the arrangement of the noncentral parts 242 of the sub-pattern 24-2 have a mirror symmetry. The plane (not shown) parallel to the Y-Z plane is a mirror plane between the sub-patterns 24-1 and 24-2. The sub-pattern 24-3 abuts the sub-pattern 24-2 and is opposite to the sub-pattern 24-1. The arrangement of the noncentral parts 242 of the sub-pattern 24-1 and the arrangement of the noncentral parts 242 of the sub-pattern 24-3 have a rotational symmetry. In some embodiments, a center of rotational symmetry (not shown) of the sub-patterns 24-1 and 24-3 passes through or overlaps the central part 241. In some embodiments, the arrangement of the noncentral parts 242 of the sub-pattern 24-3 can be obtained by rotating the noncentral parts 242 of the sub-pattern 24-1 around the center of rotational symmetry by 180°. The sub-pattern 24-4 abuts the sub-pattern 24-1. The arrangement of the noncentral parts 242 of the sub-pattern 24-1 and the arrangement of the noncentral parts 242 of the sub-pattern 24-4 have a mirror symmetry. The plane (not shown) parallel to the X-Z plane is a mirror plane between the sub-patterns 24-1 and 24-4. In some embodiments, the noncentral parts 242 at the interface (not shown) of the sub-patterns 24-1, 24-2, 24-3, and/or 24-4 may be cut. As a result, each of the noncentral parts 242 at the interface of the sub-patterns 24-1, 24-2, 24-3, and/or 24-4 may be composed of a part of an elliptical profile or an imperfectly elliptical profile. Each of the noncentral parts 242 at the interface of the sub-patterns 24-1, 24-2, 24-3, and/or 24-4 has an irregular profile. For example, the noncentral parts 242 at the interface of the sub-patterns 24-1, 24-2, 24-3, and/or 24-4 may have a profile composed of two cut noncentral parts 242, such as a profile composed of two imperfectly elliptical profiles.

Please refer back to FIG. 3A: the pattern 22 defines a pattern dimension encircled by a dotted line, which is defined as an imaginary minimum area (e.g., a rectangle) to completely enclose the central part 221 and all noncentral parts 222 as shown in FIG. 3B. The pattern 24 defines a pattern dimension encircled by a dotted line, which is defined as an imaginary minimum area (e.g., a rectangle) to completely enclose the central part 241 and all noncentral parts 242 as shown in FIG. 3C. In some embodiments, the pattern dimension of the pattern 22 may be greater than the pattern dimension of the pattern 24. The pattern dimension of the pattern 22 has a dimension L1 (e.g., a length) along the X-axis and a dimension L3 (e.g., a length) along the Y-axis. The pattern dimension of the pattern 24 has a dimension L2 (e.g., a length) along the X-axis and a dimension L4 (e.g., a length) along the Y-axis. In some embodiments, the dimension L1 is different from the dimension L3. In some embodiments, the dimension L2 is different from the dimension L2. In some embodiments, the dimension L1 of the pattern 22 is greater than the dimension L2 of the pattern 24. In some embodiments, a ratio between the dimensions L2 and L1 ranges from about 0.8 to about 0.99, such as 0.8, 0.85, 0.9, 0.95, 0.96, 0.97, and 0.99. When said ratio ranges from about 0.8 to about 0.99, the sensitivity to an OVL shift can be adjusted delicately. In some embodiments, a ratio between the pattern dimension of the patterns 22 and 24 ranges from about 0.6 to about 0.99, such as 0.6, 0.7, 0.8, 0.85, 0.9, 0.95, 0.96, 0.97, and 0.99. In some embodiments, the central part 221 may overlap or be aligned with the central part 241 along the Z-axis.

FIG. 3D illustrates a top view of the central parts 221 and 241 as well as the noncentral parts 222 and 242 as shown in FIG. 3A to FIG. 3C. In some embodiments, the central part 221 has a circular profile which has a diameter R1. In some embodiments, the central part 241 has a circular profile which has a diameter R2. In some embodiments, a ratio between the diameters R2 and R1 ranges from about 0.8 to about 0.99, such as 0.8, 0.85, 0.9, 0.95, 0.96, 0.97, and 0.99. In some embodiments, the noncentral part 222 has an elliptical profile which has a long axis with a dimension E1 (e.g., a length) and a short axis dimension E2 (e.g., a length). In some embodiments, a ratio between the dimensions E1 and E2 ranges from about 1.2 to about 5, such as 1.2, 1.3, 1.5, 2, 3, and 5. In some embodiments, the noncentral part 242 has an elliptical profile which has a long axis with a dimension E3 (e.g., a length) and a short axis dimension E4 (e.g., a length). In some embodiments, a ratio between the dimensions E3 and E4 ranges from about 1.2 to about 5, such as 1.2, 1.3, 1.5, 2, 3, and 5.

Referring to FIG. 3E, the noncentral parts 222 define rows R1, R2, R3, R4, R5, R6, R7, R8, R9, R10, R11, R12, and R13. The noncentral parts 222 define a vortex arrangement (or a spiral arrangement). For example, the noncentral parts 222 of the same row are substantially aligned with each other along the X-axis; two noncentral parts 222 of abutting rows are misaligned along the Y-axis. For example, the noncentral parts 222 of the row R12 are aligned with each other along the X-axis; one of the noncentral parts 222 of the row R10 is misaligned with an abutting noncentral part 222 (or the closest noncentral part 222) of the row R11. In some embodiments, the gravity centers of the closet noncentral parts 222 in different rows R1 to R13 define a curved line.

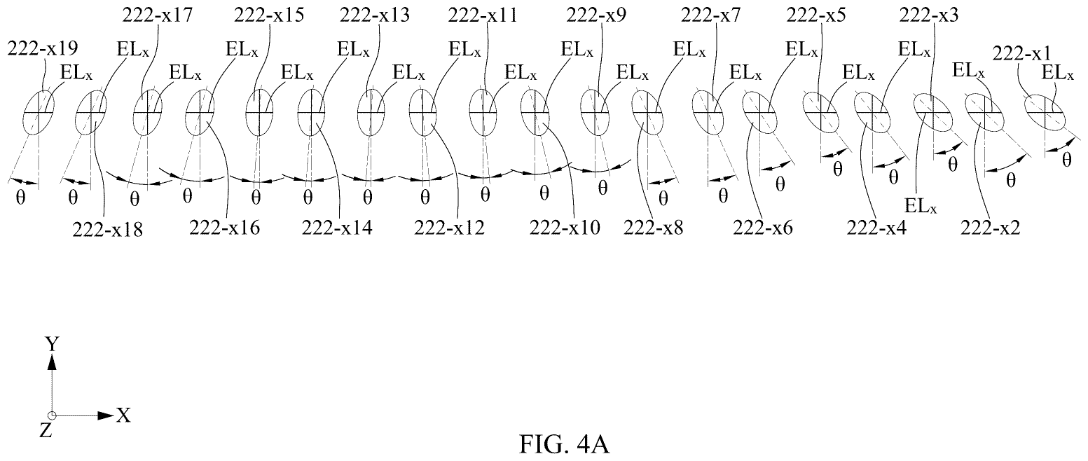

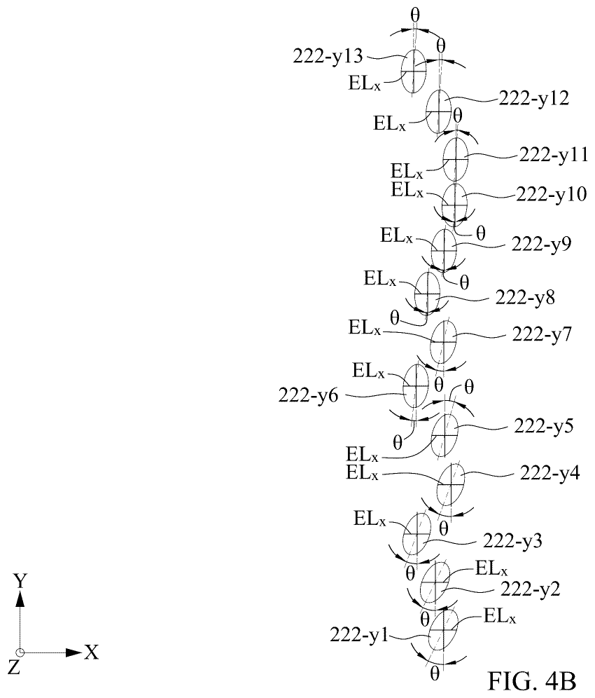

FIG. 4A is an enlarged view of region R1 as shown in FIG. 3B. In some embodiments, each of or two abutting noncentral parts 222 in the X-axis have different effective length ELₓ along the X-axis. For example, the centers (e.g., gravity centers) of the noncentral parts 222-x1, 222-x2, 222-x3, 222-x4, 222-x5, 222-x6, 222-x7, 222-x8, 222-x9, 222-x10, 222-x11, 222-x12, 222-x13, 222-x14, 222-x15, 222-x16, 222-x17, 222-x18, and 222-x19 are aligned along the X-axis. The noncentral part 222-x1 is the closest to the central part 221. The noncentral part 222-x19 is the farthest away from the central part 221. In some embodiments, the noncentral parts 222-x1 to 222-x19 have different effective lengths ELₓ along the X-axis. As used herein, the term “effective length along the X-axis (or Y-axis)” indicates a distance between two points passing through the center (e.g., gravity center) of the measured object (e.g., noncentral parts 222) along the X-axis (or Y-axis). In some embodiments, the noncentral parts 222-x1 to 222-x19 have the same surface area.

In some embodiments, the angles θ between the long axes of the noncentral part 222-x1 to 222-x19 and the Y-axis are different. For example, the angle θ between the Y-axis and the long axis of the noncentral part 222-x1 has a relatively large absolute value and thus has a greater effective length ELₓ along the X-axis. The angle θ between the Y-axis and the long axis of the noncentral part 222b-x13 is substantially equal to 0 and has a minimum effective length ELₓ along the X-axis. The angle θ between the Y-axis and the long axis of the noncentral part 222x-19 has a relatively large absolute value and thus has a greater effective length ELₓ along the X-axis.

FIG. 4B illustrates region R2 as shown in FIG. 3B. The noncentral parts 222-y1, 222-y2, 222-y3, 222-y4, 222-y5, 222-y6, 222-y7, 222-y8, 222-y9, 222-y10, 222-y11, 222-y12, and 222-y13 are located at the outermost part of the pattern 22. In some embodiments, the noncentral parts 222 have a standard deviation of an effective length ELₓ along the Y-axis which is smaller than a standard deviation of an effective length ELₓ along the X-axis. For example, the noncentral parts 222-y1 to 222-y13 have a smaller standard deviation of an effective length ELₓ than the noncentral parts 222-x1 to 222-x19 have.

In some embodiments, the noncentral parts 222 have a standard deviation of angles θ between the Y-axis and the long axis of each of the noncentral parts 222 along the Y-axis which is smaller than a standard deviation of angles θ between the Y-axis and the long axis of each of the noncentral parts 222 along the X-axis. For example, the noncentral parts 222-y1 to 222-y13 have a smaller standard deviation of angles θ than the noncentral parts 222-x1 to 222-x19 have.

By such arrangement, the measurement target 2 has a greater sensitivity of the OVL shift in the X-axis than a sensitivity of the OVL shift in the Y-axis.

The measurement target 2 can be utilized to measure an OVL shift of the pre-layer and the present layer of a substrate. For example, the measurement target 2 can be utilized to detect X-OVL shift, Y-OVL shift, or a combination thereof. Further, the measurement target 2 has an excellent sensitivity to an angle shift and an expansion shift of OVL, which is caused by the warpage of a substrate, in comparison with conventional overlay marks. In this embodiment, each of the pre-layer (e.g., pattern 22) and the present layer (e.g., pattern 24) of the measurement target 2 has a central part and noncentral parts surrounding the central part. The patterns 22 and 24 have different dimensions and thus form a moiré pattern, which includes overlaying similar but slightly offset patterns. Each of the patterns 22 and 24 has a vortex arrangement, resulting in different sensitivities of the X-OVL shift and Y-OVL shift. In this embodiment, the OVL shift of the measurement target 2 can be detected by an optical microscope (OM) image, which is free of damaging the surface of a substrate. In a comparative overlay mark, an OVL shift is detected by a scanning electron microscope (SEM) image, which damages the surface of a substrate. Further, the OVL shift of the measurement target 2 can be detected quickly because of its great sensitivity, which thereby improves the cycle time of manufacturing process.

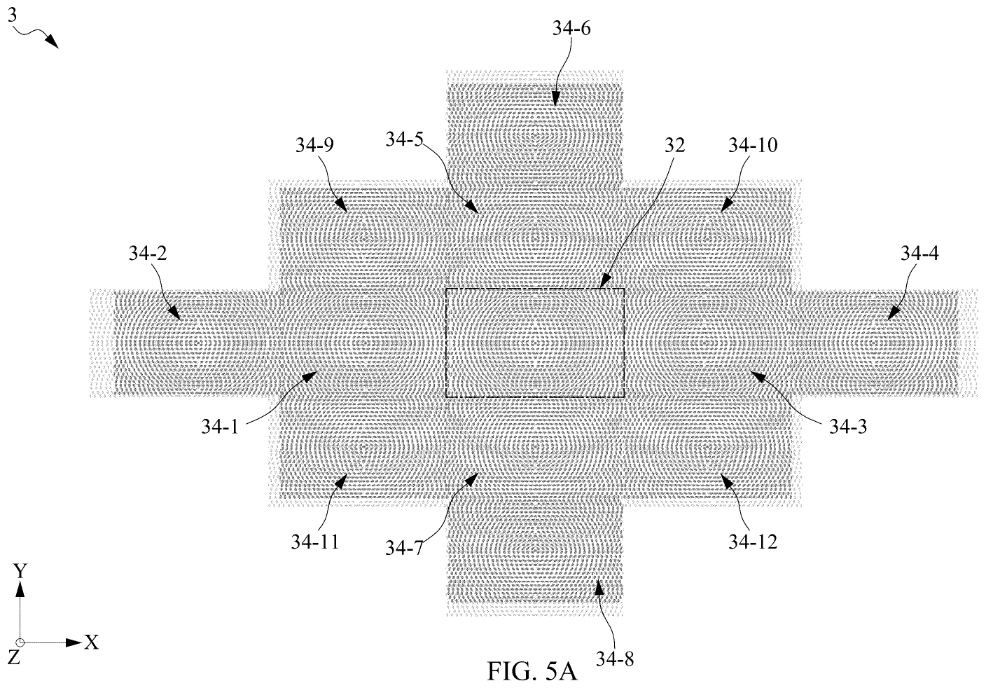

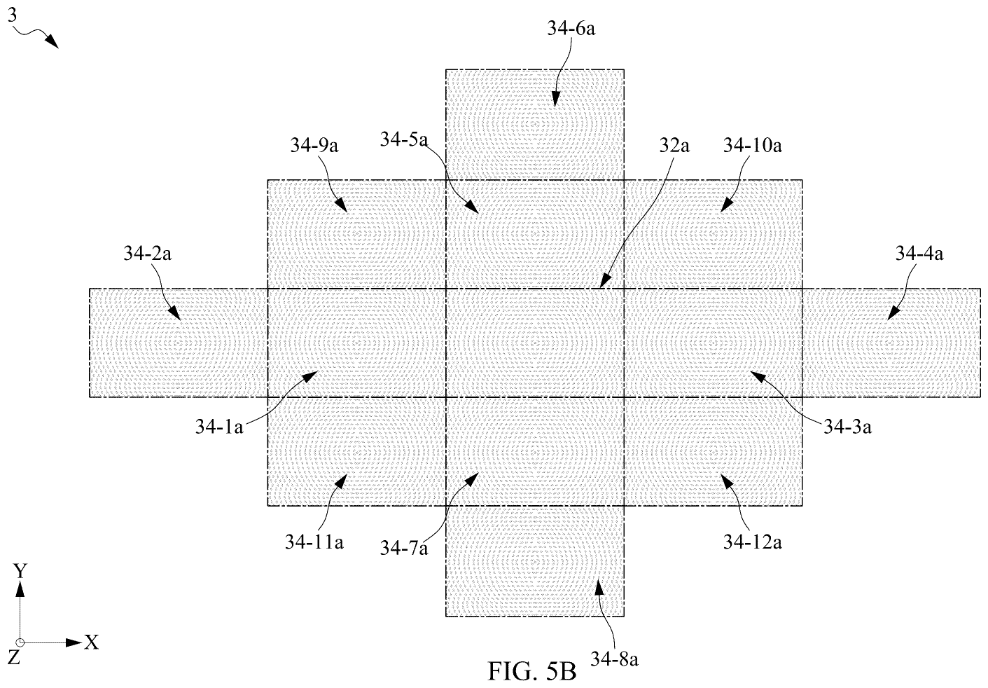

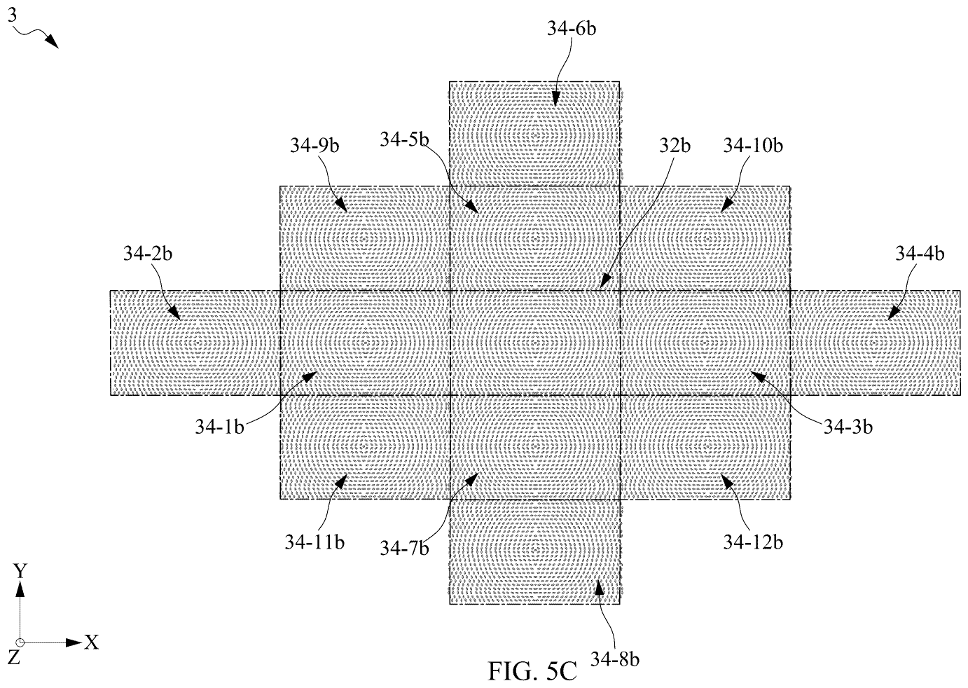

FIG. 5A is a top view of a measurement target 3 for aligning different layers of a substrate according to various aspects of the present disclosure.

In some embodiments, the measurement target 3 may include multiple cells 32, 34-1, 34-2, 34-3, 34-4, 34-5, 34-6, 34-7, 34-8, 34-9, 34-10, 34-11, and 34-12, each of which may be the same as or similar to the measurement target 2 as shown in FIG. 2A.

In some embodiments, the cell 32 is located at the center of the measurement target 3, and is also referred to as “a central cell.” In some embodiments, the cells 34-1 to 34-12 surround the cell 32, and are also referred to as “noncentral cells.” The cells 32, 34-1, 34-2, 34-3, and 34-4 are aligned along the X-axis. The cell 34-1 is located between the cells 34-2 and 32. The cell 34-1 abuts the cells 32 and 34-2. The cell 34-3 is located between the cells 34-4 and 32. The cells 34-1 and 34-3 are located on two opposite sides of the cell 32. The cells 32, 34-5, 34-6, 34-7, and 34-8 are aligned along the Y-axis. The cell 34-5 is located between the cells 34-6 and 32. The cell 34-7 is located between the cells 34-8 and 32. The cells 34-5 and 34-7 are located on two opposite sides of the cell 32. The cells 34-9 to 34-12 are located on four corners of the cell 32. The cell 34-9 abuts the cells 34-1 and 34-5. The cell 34-10 abuts the cells 34-3 and 34-5. The cell 34-11 abuts the cells 34-1 and 34-7. The cell 34-12 abuts the cells 34-3 and 34-7.

In some embodiments, each of the cells 32 and 34-1 to 34-12 has a first pattern (or a pre-layer) located at a first layer of a substrate and a second pattern (or a present layer) located at a second layer, which is above or under the first layer, of the substrate. As shown in FIG. 5B, each of the cells 32 and 34-1 to 34-12 has patterns 32a, 34-1a, 34-2a, 34-3a, 34-4a, 34-5a, 34-6a, 34-7a, 34-8a, 34-9a, 34-10a, 34-11a, and 34-12a, respectively. In some embodiments, the patterns 32a and 34-1a to 34-12a may have the same arrangements. In some embodiments, the patterns 32a and 34-1a to 34-12a may have the same pattern dimensions (e.g., pattern areas). In some embodiments, the pattern boundaries of two abutting patterns 32a and 34-1a to 34-12a overlap or are aligned. As used herein, the pattern boundary can be defined as an imaginary area, such as a rectangle, enclosing all parts of the pattern, and the pattern dimension can be defined as an area enclosed by the pattern boundary.

As shown in FIG. 5C, each of the cells 32 and 34-1 to 34-12 has patterns 32b, 34-1b, 34-2b, 34-3b, 34-4b, 34-5b, 34-6b, 34-7b, 34-8b, 34-9b, 34-10b, 34-11b, and 34-12b, respectively. In some embodiments, the patterns 32b and 34-1b to 34-12b have the same arrangements. In some embodiments, the patterns 32b and 34-1b to 34-12b have the same pattern dimensions (e.g., pattern areas). In some embodiments, the pattern boundaries of the abutting patterns 32b and 34-1b to 34-12b overlap or are aligned.

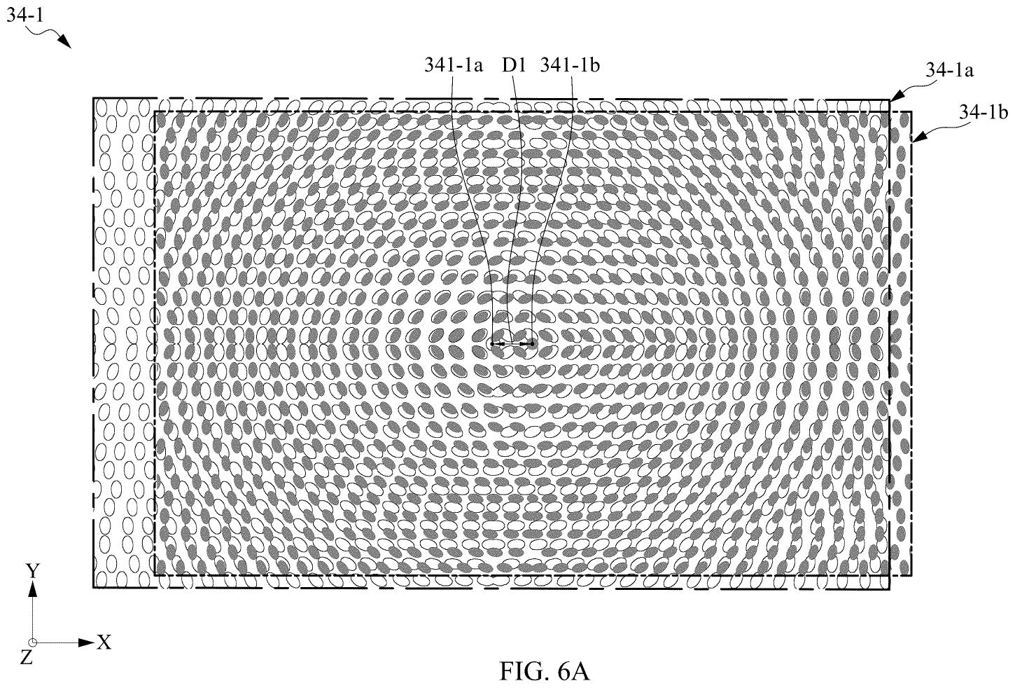

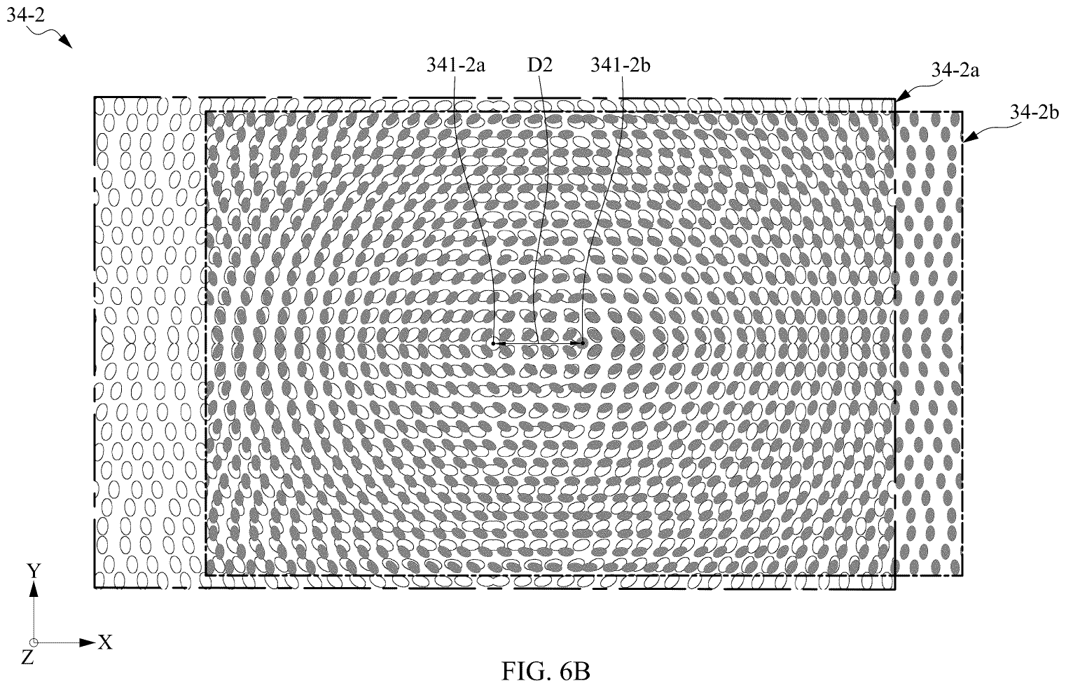

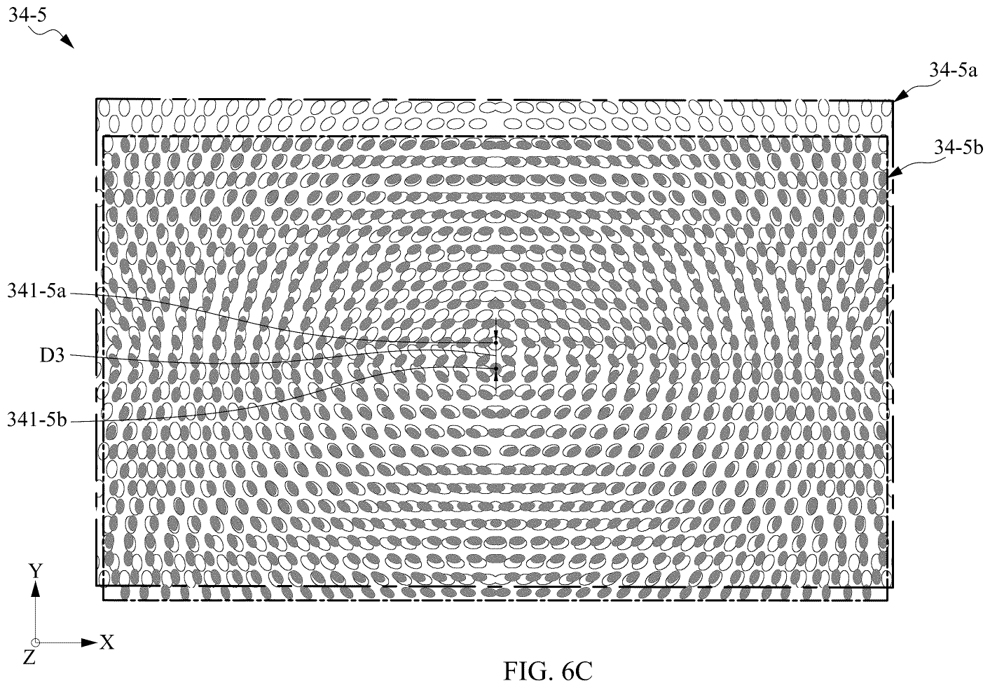

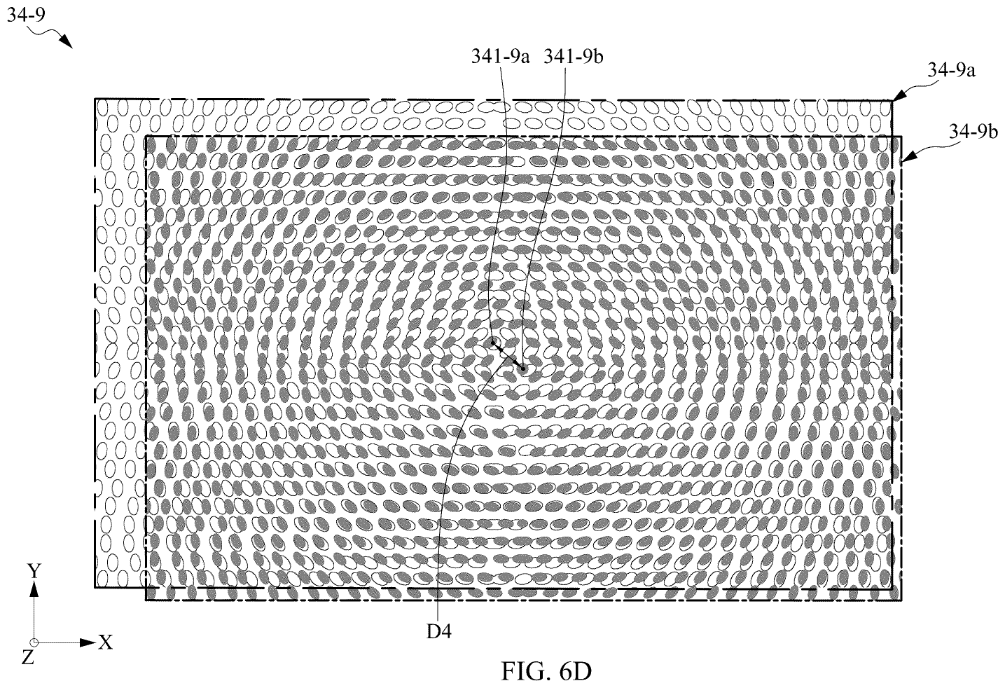

In some embodiments, the central part of the pattern 32a is aligned with or overlaps the central part of the pattern 32b along the Z-axis. Since the pattern boundaries of the abutting patterns 32a and 34-1a to 34-12a overlap and the pattern boundaries of the abutting patterns 32b and 34-1b to 34-12b overlap, part of the central part of the first pattern (e.g., patterns 34-1a to 34-12a) is misaligned with central part of the second pattern (e.g., patterns 34-1b to 34-12b) as shown in FIG. 5A, which will be described in FIG. 6A to FIG. 6D. In some embodiments, the first pattern of the patterns 32a and 34-1a to 34-12a at least partially overlaps the second pattern of abutting patterns 32b and 34-1b to 34-12b along the Z-axis.

FIG. 6A is an enlarged view of the cell 34-1 as shown in FIG. 5A. The cell 34-1 has a central part 341-1a and a central part 341-1b. In some embodiments, the central part 341-1a is misaligned with the central part 341-1b along the Z-axis. In some embodiments, the central part 341-1a and central part 341-1b have a shift D1 along the X-axis.

FIG. 6B is an enlarged view of the cell 34-2 as shown in FIG. 5A. The cell 34-2 has a central part 341-2a and a central part 341-2b. In some embodiments, the central part 341-2a is misaligned with the central part 341-2b along the Z-axis. In some embodiments, the central part 341-2a and central part 341-2b have a shift D2 along the X-axis. In some embodiments, the shift D2 is greater than the shift D1.

FIG. 6C is an enlarged view of the cells 34-5 as shown in FIG. 5A. The cell 34-5 has a central part 341-5a and a central part 341-5b. In some embodiments, the central part 341-5a is misaligned with the central part 341-5b along the Z-axis. In some embodiments, the central part 341-5a and central part 341-5b have a shift D3 along the Y-axis.

FIG. 6D is an enlarged view of the cells 34-9 as shown in FIG. 5A. The cell 34-9 has a central part 341-9a and a central part 341-9b. In some embodiments, the central part 341-9a is misaligned with the central part 341-9b along the Z-axis. In some embodiments, the central part 341-9a and central part 341-9b have a shift D4 along a direction nonparallel to the X-axis and the Y-axis.

By such arrangement, each of the cells 32 and 34-1 to 34-12 exhibits a different sensitivity to an OVL shift along both the X-axis and the Y-axis. For example, each of the cells 32, 34-9, 34-10, 34-11, and/or a combination thereof has a greater sensitivity to an OVL shift along the X-axis. Each of the cells 34-1, 34-3, 34-5, 34-7, and/or a combination thereof has a greater sensitivity to an OVL shift along the Y-axis. Each of the cells 34-1, 34-3, 34-5, 34-7, and/or a combination thereof has a greater sensitivity to an OVL shift along the Y-axis. Each of the cells 34-4, 34-6, 34-8, 34-11, and/or a combination thereof has a greater sensitivity to a relatively large OVL shift. Therefore, the measurement target 3 provides a simple method for determining the type of OVL shift. Further, such determination can be achieved by an image of the OM. In this embodiment, the measurement target 3 can detect an OVL shift of 5 nm or less by an image of the OM.

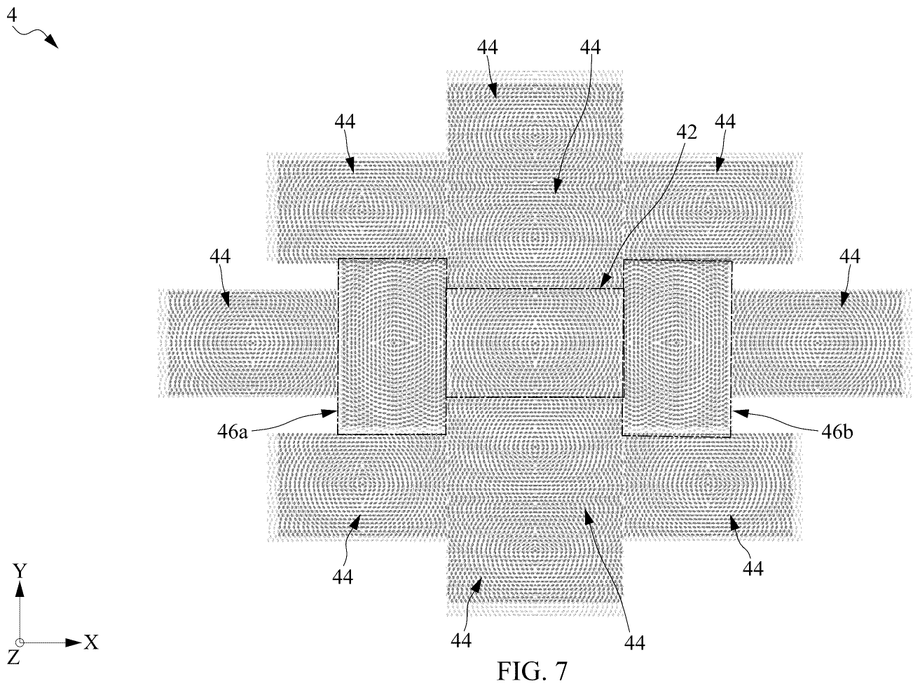

FIG. 7 is a top view of a measurement target 4 for aligning different layers of a substrate according to various aspects of the present disclosure.

In some embodiments, the measurement target 4 includes a cell 42, a plurality of cells 44, a cell 46a and a cell 46b. The cell 42 has an arrangement which is the same as that of the cell 32 as shown in FIG. 5A. Each of the cells 44 has an arrangement which is the same as that of one of the cells 34-1 to 34-12 as shown in FIG. 5A. In some embodiments, the arrangement of the cells 46a and/or 46b is the same as an arrangement of the cell 42 rotating around a rotational axis parallel to the Z-axis by 90°. For example, when the cell 42 is rotated 90° around its central part, the rotated pattern has an arrangement which is the same as that of the cells 46a and/or 46b. The cell 42 defines a first cell length along the X-axis and a second cell length along the Y-axis, and the first cell length is greater than the second cell length. Each of the cells 46a and 46b defines a third cell length along the X-axis and a fourth cell length along the Y-axis, and the third cell length is less than the fourth cell length.

The cells 46a and/or 46b can provide different sensitivities in comparison with the plurality of cells 44, which thereby provide multiple combinations to detect different types of OVL shifts.

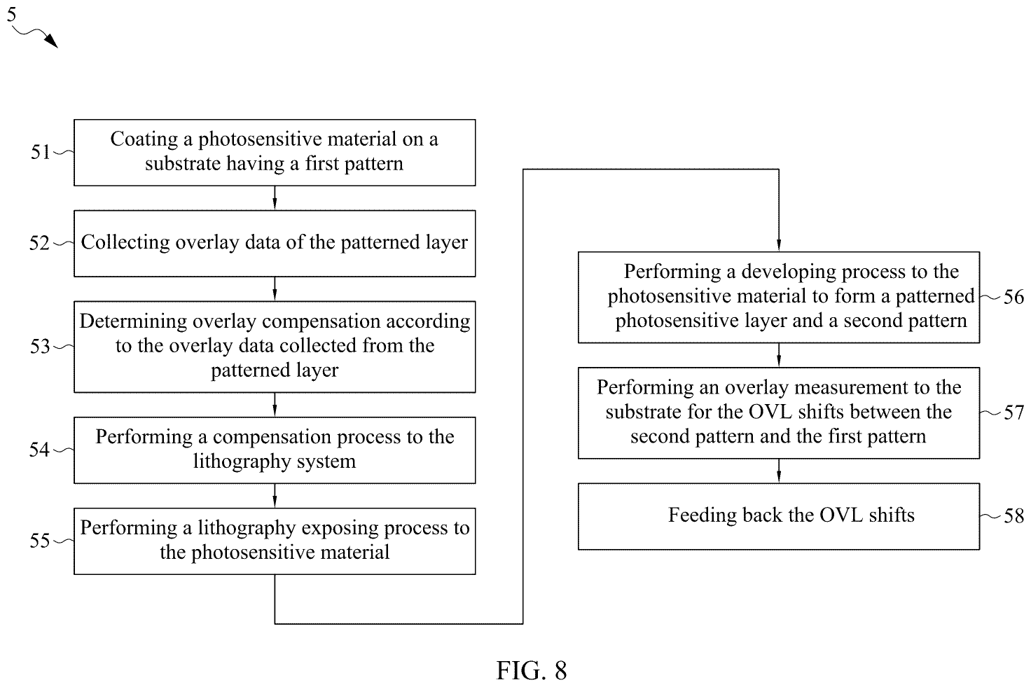

FIG. 8 is a flowchart of a method 5 for fabricating an integrated circuit (IC) structure, constructed in accordance with some embodiments. The method 5 may begin at operation 51 by coating a photosensitive material on a substrate. In some embodiments, the substrate is a semiconductor substrate, such as silicon substrate or a substrate having another semiconductor material (e.g., silicon germanium).

In the present embodiment, the substrate includes a semiconductor wafer (such as a silicon wafer) having a patterned layer. The patterned layer includes a first pattern (e.g., the pattern 22 as shown in FIG. 3A), for overlay inspection, formed in a first material layer located at a first level. The first pattern also includes various measurement targets designed for alignment monitoring and overlay inspection. The first material layer of the patterned layer may include a semiconductor material layer (such as a silicon layer or silicon germanium layer), a dielectric material (such as an interlayer dielectric-ILD) or a conductive material (such as a metal layer or a doped polysilicon layer) in various embodiments. The first material layer is patterned to form the first pattern by a suitable technology (such as lithography patterning) and by a grating (or a mask) including a pattern, such as a pattern 22 as shown in FIG. 3A. In various embodiments, the first material layer includes a main feature, such as a doping pattern (such as various source and drain features formed in a semiconductor material layer), a gate electrode pattern (having multiple gate electrodes of polysilicon or metal), or an interconnect pattern having a plurality of conductive features (such as contacts, vias, or metal lines).

The substrate may include a second material layer to be patterned in subsequent operations to form a target feature in a way that a target pattern is aligned to the main feature.

In some embodiments, the second material layer is disposed on the patterned layer and includes a semiconductor material layer (such as a silicon layer or silicon germanium layer), a dielectric material (such as silicon oxide, silicon nitride or low k dielectric material layer) or a conductive material (such as a doped polysilicon layer, a copper layer, or an aluminum layer). In one embodiment, the main feature of the patterned layer includes source and drain features and the target feature to be formed in the second material layer includes contacts designed to land on the source and drain features. In another embodiment, the main feature of the patterned layer includes a plurality of metal lines and the target feature includes via features designed to land on the metal lines. In alternative embodiments, the target feature is also to be formed in the patterned layer, such as in double patterning. In those cases, the second material layer may be eliminated. In one example for illustrating a double patterning process, the main feature is formed in a hard mask layer, and the target feature is subsequently formed in the same hard mask layer. The combined pattern, including the first and target features, is then transferred from the hard mask to an underlying material layer with a reduced pattern pitch.

In the operation 51, a photosensitive material is coated on the substrate by a proper technique, such as spin-on coating. The photosensitive material is sensitive to the radiation beam during a lithography exposing process and is resistive to a subsequent process (such as etching or ion implantation). In some embodiments, the photosensitive material includes a polymeric material as a matrix that is resistive; a radiation-sensitive component (such as a photo-acid generator or PAG); and a solvent. The photosensitive material may be positive-tone resist or negative tone resist. The operation 51 may further include other processing steps, such as a thermal baking step to reduce the solvent content of the photosensitive material after the spin-on coating.

The method 5 includes an operation 52 by collecting overlay data of the patterned layer. In some embodiments, the overlay data includes the locations of the first pattern (e.g., the pattern 22 as shown in FIG. 3A) or a map of the first pattern in the patterned layer.

In some embodiments, the collecting of the overlay data of the patterned layer is implemented in one or more standalone overlay metrology tools (an offline mode).

In some embodiments, the collecting of the overlay data of the patterned layer is implemented in an inline mode, specifically inside a lithography system that is used to perform the exposing process on the photosensitive material.

The lithography system includes a radiation source (or source) to provide radiation energy. The radiation source may be any suitable light source. In various embodiments, the radiation source may include a light source selected from the group consisting of an ultraviolet (UV) source, a deep UV (DUV) source, and an EUV source. For example, the radiation source may be a mercury lamp having a wavelength of 436 nm (G-line) or 365 nm (I-line); a Krypton Fluoride (KrF) excimer laser with wavelength of 248 nm; an Argon Fluoride (ArF) excimer laser with a wavelength of 193 nm; a Fluoride (F₂) excimer laser with a wavelength of 157 nm; or other light sources having a desired wavelength (e.g., below approximately 100 nm). In another example, the light source has a wavelength of about 13.5 nm or less.

The method 5 includes an operation 53 by determining overlay compensation according to the overlay data collected from the patterned layer using an alignment model. The overlay compensation is determined according to the OVL shifts using the alignment model.

The method 5 includes an operation 54 by performing a compensation process to the lithography system according to the overlay compensation determined at the operation 53. During the operation 54, the lithography system is adjusted according to the overlay compensation. By the operation 54, the lithography system is corrected to reduce the OVL shifts in a feed forward manner since the overlay compensation is determined based on the overlay data from the wafer and the subsequent exposing process is applied to the same wafer by the corrected lithography system.

The method 5 includes an operation 55 by performing a lithography exposing process to the photosensitive material in the lithography system. During the lithography exposing process, the radiation beam from the radiation source is directed to the mask (or grating) and further directed to the photosensitive material.

The method 5 may include an operation 56 by performing a developing process to the photosensitive material to form a patterned photosensitive layer. For example where the photosensitive material is positive tone resist, the exposed portion of the photosensitive material will be removed by the developing process. In another example where the photosensitive material is negative tone resist, the unexposed portion of the photosensitive material will be removed by the developing process, but the exposed portion remains. The patterned photosensitive material includes the main circuit pattern and a second pattern (e.g., the pattern 24 as shown in FIG. 3) of the measurement target. In some embodiments, the operation 56 may further include other steps, such as post exposure baking (PEB) prior to the developing process and/or hard baking after the exposing process.

The method 5 may include an operation 57 by performing an overlay measurement to the substrate for the OVL shifts between the patterned photosensitive material and the patterned layer or between the second pattern and the first pattern. The overlay measurement, at this stage, is able to directly measure the displacement errors between the first pattern and the second pattern of the measurement target in pairs. The overlay measurement in the operation 57 is implemented in a suitable overlay metrology tool that is operable to simultaneously image both first and second measurement targets.

The method 5 may further include an operation 58 by feeding back the OVL shifts measured at operation 57 to the lithography system.

In some embodiments, the measured OVL shifts may be fed back for additional tuning/adjustment of the lithography system. For example, the operation includes determining overlay compensation from the measured OVL shifts using the alignment model, and performing an overly compensation process on the lithography system to adjust one or more compensation parameters. In some embodiments, the measured OVL shifts may be fed back to the alignment model so that the alignment model is tuned accordingly. For example, the operation includes adjusting various coefficients in the mathematical formula of the alignment model according to the measured OVL shifts.

Some embodiments of the present disclosure provide a semiconductor device. The semiconductor device includes a first pattern and a second pattern. The first pattern includes a first central part and a plurality of first noncentral parts surrounding the first central part and spaced apart from each other. The second pattern is at a second layer over the first layer of the substrate and at least partially overlapping the first pattern along a first direction passing through the first layer and the second layer. The plurality of first noncentral parts define a vortex arrangement.

Some embodiments of the present disclosure provide a semiconductor device. The semiconductor device includes a first pattern and a second pattern. The first pattern is at a first layer of a substrate. The first pattern includes a first central part and a plurality of first noncentral parts surrounding the first central part. The second pattern is at a second layer over the first layer of the substrate and at least partially overlaps the first pattern along a first direction. Each of the plurality of first noncentral parts has a corresponding long axis extending along different directions.

Some embodiments of the present disclosure provide a semiconductor device. The semiconductor device includes a first cell and a second cell. The first cell includes a first pattern and a second pattern. The first pattern is located at a first layer of a substrate. The first pattern includes a first central lattice. The second pattern is at a second layer over the first layer of the substrate and at least partially overlaps the first pattern along a first direction. The second pattern includes a second central lattice substantially aligned with the first central lattice along the first direction. The second cell includes a third pattern and a fourth pattern. The third pattern is at the first layer and includes a third central lattice. The fourth pattern is at the second layer and at least partially overlaps the third pattern along the first direction. The fourth pattern includes a fourth central lattice misaligned with the third central lattice along the first direction.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first pattern at a first layer of a substrate, wherein the first pattern comprises a first central part and a plurality of first noncentral parts surrounding the first central part and spaced apart from each other; and
a second pattern at a second layer over the first layer of the substrate and at least partially overlapping the first pattern along a first direction passing through the first layer and the second layer,
wherein the plurality of first noncentral parts define a vortex arrangement.

2. The semiconductor device of claim 1, wherein the plurality of first noncentral parts define a plurality of rows, the plurality of first noncentral parts in the same row are aligned along a second direction orthogonal to the first direction, and the plurality of first noncentral parts in abutting two rows are misaligned along a third direction orthogonal to the first direction and the second direction.

3. The semiconductor device of claim 1, wherein the second pattern comprises a second central part and a plurality of corresponding second noncentral parts surrounding the second central part, and a first part dimension of one of the plurality of first noncentral parts is different from a second part dimension of one of the plurality of corresponding second noncentral parts.

4. The semiconductor device of claim 3, wherein the first central part is free from overlapping with the second central part along the first direction.

5. The semiconductor device of claim 3, wherein the first central part is aligned with the second central part along the first direction.

6. The semiconductor device of claim 1, wherein a profile of one of the plurality of first noncentral parts is different from a profile of the first central part.

7. The semiconductor device of claim 6, wherein the one of the plurality of first noncentral parts has an elliptical profile.

8. The semiconductor device of claim 6, wherein the first central part has a circular profile.

9. The semiconductor device of claim 2, wherein the plurality of first noncentral parts comprises a first subpart and a second subpart aligned with the first subpart along a second direction substantially orthogonal to the first direction, the first subpart has a first effective length along the second direction, and the second subpart has a second effective length different from the first effective length along the second direction.

10. The semiconductor device of claim 9, wherein a first surface area of the first subpart is the same as a second surface area of the second subpart.

11. A semiconductor device, comprising:
a first pattern at a first layer of a substrate, wherein the first pattern comprises a first central part and a plurality of first noncentral parts surrounding the first central part; and
a second pattern at a second layer over the first layer of the substrate and at least partially overlapping the first pattern along a first direction,
wherein each of the plurality of first noncentral parts has a corresponding long axis extending along different directions.

12. The semiconductor device of claim 11, wherein at least one of the plurality of first noncentral parts has an elliptical profile.

13. The semiconductor device of claim 11, wherein the first pattern defines a first pattern dimension, and the second pattern defines a second pattern dimension different from the first pattern dimension.

14. A semiconductor device, comprising:
a first cell comprising:
a first pattern at a first layer of a substrate, wherein the first pattern comprises a first central part; and
a second pattern at a second layer over the first layer of the substrate and at least partially overlapping the first pattern along a first direction, wherein the second pattern comprises a second central part substantially aligned with the first central part along the first direction; and
a second cell, comprising:
a third pattern at the first layer and comprising a third central part; and
a fourth pattern at the second layer and at least partially overlapping the third pattern along the first direction, wherein the fourth pattern comprises a fourth central part misaligned with the third central part along the first direction.

15. The semiconductor device of claim 14, wherein the first pattern comprises a plurality of first noncentral parts surrounding the first central part, and at least one of the plurality of first noncentral parts comprises an elliptical profile.

16. The semiconductor device of claim 15, wherein the second pattern comprises a plurality of second noncentral parts surrounding the second central part, the third pattern comprises a plurality of third noncentral parts surrounding the third central part, and the plurality of third noncentral parts at least partially overlap the plurality of second noncentral parts.

17. The semiconductor device of claim 14, further comprising:
a fifth pattern at the first layer and comprising a fifth central part; and
a sixth pattern at the second layer and comprising a sixth central part misaligned with the fifth central part along the first direction,
wherein a shift between the third central part and the fourth central part is different from a shift between the fifth central part and the sixth central part along a second direction different from the first direction.

18. The semiconductor device of claim 14, further comprising:
a third cell, wherein an arrangement of the third cell is the same as an arrangement of the first cell rotating around a rotation axis parallel to the first direction by 90°.

19. The semiconductor device of claim 14, wherein the first cell defines a first cell length along a second direction orthogonal to the first direction and a second cell length along a third direction orthogonal to the first direction and the second direction, and the second cell length is greater than the first cell length.

20. The semiconductor device of claim 19, further comprising:
a third cell, wherein the third cell defines a third cell length along the second direction and a fourth cell length along the third direction, and the fourth cell length is less than the third cell length.
